(19) United States
(12) Patent Application Publication
(10) Pub. No.: US 2025/0372556 A1
(43) Pub. Date: Dec. 4, 2025

(54) SEMICONDUCTOR DEVICE AND METHOD FOR FABRICATING THE SAME

(71) Applicant: United Microelectronics Corp., Hsin-Chu City (TW)

(72) Inventors: Chuan-Lan Lin, Chiayi City (TW); Chu-Fu Lin, Kaohsiung City (TW); Yu-Ping Wang, Hsinchu City (TW); Chien-Ting Lin, Tainan City (TW)

(73) Assignee: United Microelectronics Corp., Hsin-Chu City (TW)

(21) Appl. No.: 18/761,332

(22) Filed: Jul. 2, 2024

(30) Foreign Application Priority Data
Jun. 4, 2024 (TW) 113120618

(51) Int. Cl. H01L 23/00; H01L 21/768; H01L 23/48; H01L 23/498

(52) U.S. Cl. CPC H01L 24/13; H01L 21/76898; H01L 23/481; H01L 23/49822; H01L 24/05; H01L 2224/05008; H01L 2224/05024; H01L 2224/13008; H01L 2224/13025; H01L 2924/15311

(57) ABSTRACT

A method for fabricating semiconductor device includes the steps of first bonding a first wafer to a second wafer to form a first stack structure, forming first bumps on one side of the first stack structure, bonding a third wafer to a fourth wafer to form a second stack structure, forming second bumps on one side of the second stack structure, and then bonding the first stack structure to the second stack structure by bonding the first bumps and the second bumps.

### BACKGROUND OF THE INVENTION

### 1. Field of the Invention

The invention relates to a method for fabricating semiconductor device, and more particularly, to a method of bonding multiple wafers for forming stack structures.

### 2. Description of the Prior Art

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (POP) devices and so on.

3DICs provide improved integration density and other advantages, such as faster speeds and higher bandwidth, because of the decreased length of interconnects between the stacked chips. However, there are quite a few challenges to be handled for the technology of 3DICs.

### SUMMARY OF THE INVENTION

According to an embodiment of the present invention, a method for fabricating semiconductor device includes the steps of first bonding a first wafer to a second wafer to form a first stack structure, forming first bumps on one side of the first stack structure, bonding a third wafer to a fourth wafer to form a second stack structure, forming second bumps on one side of the second stack structure, and then bonding the first stack structure to the second stack structure by bonding the first bumps and the second bumps.

According to another aspect of the present invention, a semiconductor device includes a first stack structure having a first wafer bonded to a second wafer and a second stack structure bonded to the first stack structure, in which the second stack structure includes a third wafer bonded to a fourth wafer. The semiconductor device further includes first bumps on a top surface of the first stack structure and second bumps on a bottom surface of the second stack structure and directly connected to the first bumps.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 illustrate a method for fabricating a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

Referring to FIGS. 1-9, FIGS. 1-9 illustrate a method for fabricating a semiconductor device according to an embodiment of the present invention. As shown in FIG. 1, a first wafer such as wafer 12 and a second wafer such as wafer 14 both made of semiconductor material are provided. Preferably, each of the wafers 12, 14 include a substrate made of semiconductor materials as the substrate could also be made of semiconductor substrate material including but not limited to for example silicon substrate, epitaxial silicon substrate, silicon carbide substrate or even a silicon-on-insulator (SOI) substrate, which are all within the scope of the present invention. In this embodiment, each of the wafers 12, 14 could be used for fabricating elements including MV devices, HV devices, pixel circuits, LV devices for LV driving circuits, and/or graphics process unit (GPU).

Next, a front end of line (FEOL) and a back end of line (BEOL) fabrication processes could be conducted on the wafers 12, 14 respectively while the wafer 12 is adhered onto the carrier 18. In this embodiment, the FEOL process could include the process of forming metal-oxide semiconductor (MOS) transistors, oxide semiconductor field effect transistors (OS FETs), fin field effect transistor (FinFETs), or other active devices and/or passive devices. BEOL process on the other hand could include forming metal interconnect structures such as metal inter-metal dielectric (IMD) layers and metal interconnections 24 on the aforementioned active devices and/or passive devices.

If a MOS transistor were to be fabricated, the FEOL process could include the steps of forming a gate structure on the substrate, forming a spacer (not shown) adjacent to sidewalls of the gate structure and a source/drain region in the substrate adjacent to two sides of the spacer, in which the gate structure could include polysilicon or metal, the spacer could include dielectric material such as silicon oxide or silicon nitride, and the source/drain region could include p-type dopants or n-type dopants depending on the conductive type of the transistor being fabricated.

Next, an interlayer dielectric (ILD) layer could be formed on the substrate to cover the MOS transistor or other active devices, and then a contact plug formation and metal interconnect process from BEOL process could be conducted to form a plurality of contact plugs in the ILD layer for connecting the source/drain region and the gate structure, an inter-metal dielectric (IMD) layer disposed on the ILD layer, and metal interconnections in the IMD layer for connecting the contact plugs, in which the topmost metal interconnection on front side of the wafers 12, 14 could be used as connecting junctions such as direct bond interconnects (DBIs) 16 as the two wafers could be bonded through DBIs 16 in the later process. In this embodiment, the ILD layer and the IMD layer could include oxides including but not limited to for example tetraethyl orthosilicate (TEOS) and the contact plugs, the metal interconnections, and the DBIs 16 could include Al, Cr, Cu, Ta, Mo, W, or combination thereof.

Next, as shown in FIG. 2, a hybrid bonding process is conducted by using the DBIs to connect the wafer 12 and the wafer 14. Preferably, the bonding process could be accomplished by first reversing the wafer 14 so that the front side of the wafer 14 or the exposed surface of the DBIs 16 is facing toward the front side of the wafer 12 or the exposed surface of the DBIs 16, and then performing a thermal treatment process to directly bond the two wafers 12, 14 by directly contacting the DBIs 16 on both wafers 12, 14 so that the DBIs 16 and IMD layer on the wafer 14 directly contacting the DBIs 16 and IMD layer on the wafer 12 thereby forming a first stack structure 18.

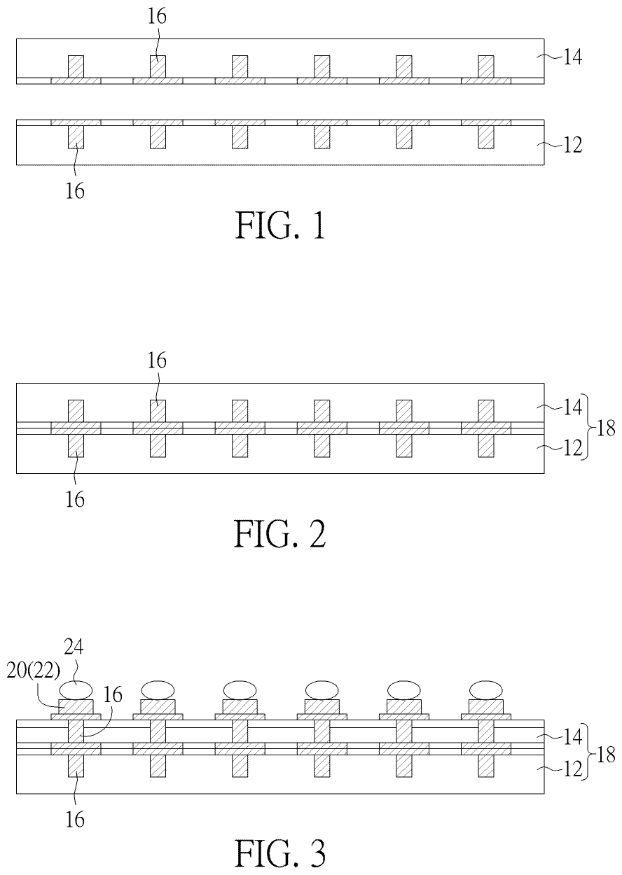

Next, as shown in FIG. 3, a bonding pad formation is conducted by forming a redistribution layer (RDL) 20 and bonding pads 22 on a side such as top surface of the wafer 14 or first stack structure 18 and then forming bumps 24 such as micro bumps or solder balls on the bonding pads 22. In this embodiment, the RDL 20, the bonding pads 22, and the bumps 24 could include aluminum (Al), copper (Cu), silver (Ag), gold (Au), nickel (Ni), tungsten (W), or alloy thereof.

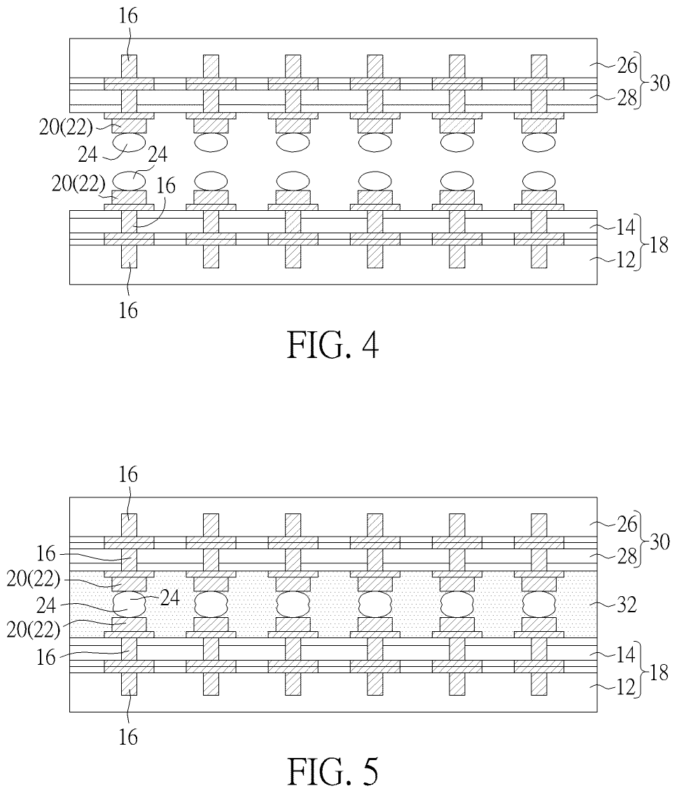

Next, as shown in FIG. 4, a third wafer such as wafer 26 is bonded to a fourth wafer such as wafer 28 by following the process conducted in FIGS. 1-3 to form a second stack structure 30. Similar to the aforementioned process, FEOL and BEOL processes could be selectively conducted on the third wafer and the fourth wafer before DBIs 16 are formed on each of the wafers 26, 28. Next, a hybrid bonding process is conducted by using DBIs on each of the wafers 26, 28 to bond the wafers 26, 28 directly for forming a second stack structure 30. Next, a bonding pad formation is conducted by forming a RDL 20, bonding pads 22, and bumps 24 on one side such as top surface of the second stack structure 30, and then the second stack structure 30 is reversed so that the bumps 24 on the second stack structure 30 are facing toward the bumps 24 on the first stack structure 18.

Next, as shown in FIG. 5, a bonding process such as hybrid bonding process or micro bump bonding process could be conducted to connect the first stack structure 18 and the second stack structure 30 by bonding or directly contacting the bumps 24 on the first stack structure 18 with the bumps 24 on the second stack structure 30. A seal layer 32 is then formed thereafter between the first stack structure 18 and the second stack structure 30.

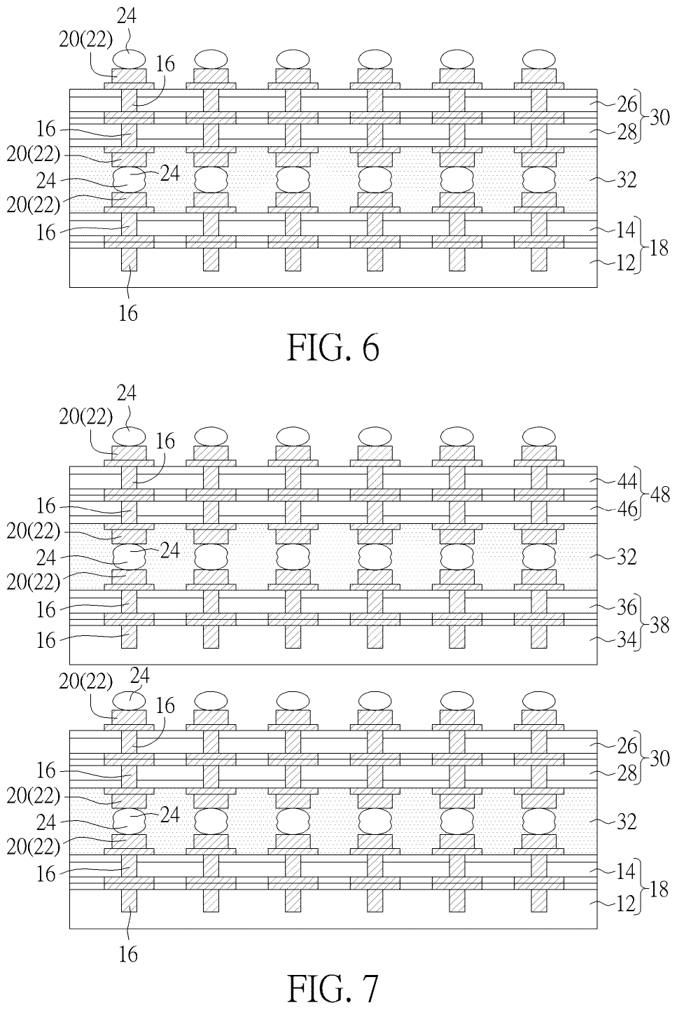

Next, as shown in FIG. 6, a bonding pad formation conducted in FIG. 3 could be carried out by forming a RDL 20, bonding pads 22, and bumps 24 on another side of the second stack structure 30.

Next, as shown in FIG. 7, the processes conducted in FIGS. 1-6 could be repeated by bonding a fifth wafer to a sixth wafer to form a third stack structure 38, bonding a seventh wafer to an eighth wafer to form a fourth stack structure 48, and then bonding the third stack structure 38 to the fourth stack structure 48.

Specifically, a fifth wafer such as wafer 34 could be bonded to a sixth wafer such as wafer 36 for forming a third stack structure 38. Similar to the aforementioned process, FEOL and BEOL processes could be carried out on the fifth wafer and the sixth wafer, DBIs 16 could be formed directly on the wafer 34 and wafer 36, and then a hybrid bonding process could be conducted to bond the wafers 34 and 36 through the DBIs 16 on each of the wafers 34, 36 for forming a third stack structure 38. Next, a bonding pad formation could be conducted to form a RDL 20, bonding pads 22, and bumps 24 on one side such as top surface of the third stack structure 38.

Next, a seventh wafer such as wafer 44 is conducted to an eighth wafer such as wafer 46 to form a fourth stack structure 48. Similarly, FEOL and BEOL processes could be carried out on the seventh wafer and the eighth wafer, DBIs 16 could be formed directly on the wafer 44 and wafer 46, and then a hybrid bonding process could be conducted to bond the wafers 44 and 46 directly through the DBIs 16 on each of the wafers 34, 36 for forming a fourth stack structure 48. Next, a bonding pad formation could be conducted to form a RDL 20, bonding pads 22, and bumps 24 on one side such as top surface of the fourth stack structure 48. The fourth stack structure 48 is then reversed so that the bumps 24 on the fourth stack structure 48 are facing toward the bumps 24 on the third stack structure 38.

Next, a bonding process such as hybrid bonding process or micro bump bonding process could be conducted to bond the third stack structure 38 and the fourth stack structure 48 through the bumps 24 on the third stack structure 38 and the bumps 24 on the fourth stack structure 48, and then a seal layer 32 is formed between the third stack structure 38 and the fourth stack structure 48 afterwards. Next, a bonding pad formation conducted in FIG. 6 could be carried out by forming a RDL 20, bonding pads 22, and bumps 24 on another side of the fourth stack structure 48.

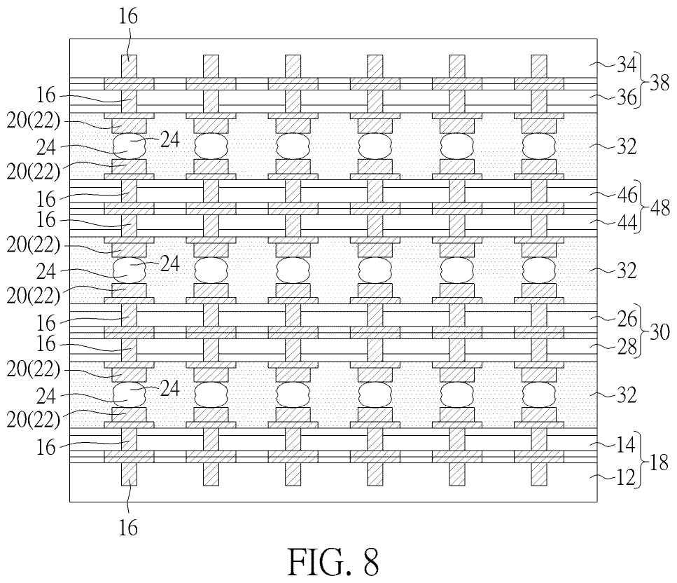

Next, as shown in FIG. 8, the third stack structure 38 and the fourth stack structure 48 could be reversed and then a bonding process such as a hybrid bonding process or micro bump bonding process could be conducted to bond the already bonded first stack structure 18 and second stack structure 30 to the bonded structure of the third stack structure 38 and fourth stack structure 48 by connecting the bumps 24 on the second structure 30 and the bumps 24 on the fourth stack structure 48. A seal layer 32 is then formed between the second stack structure 30 and the fourth stack structure 48 afterwards.

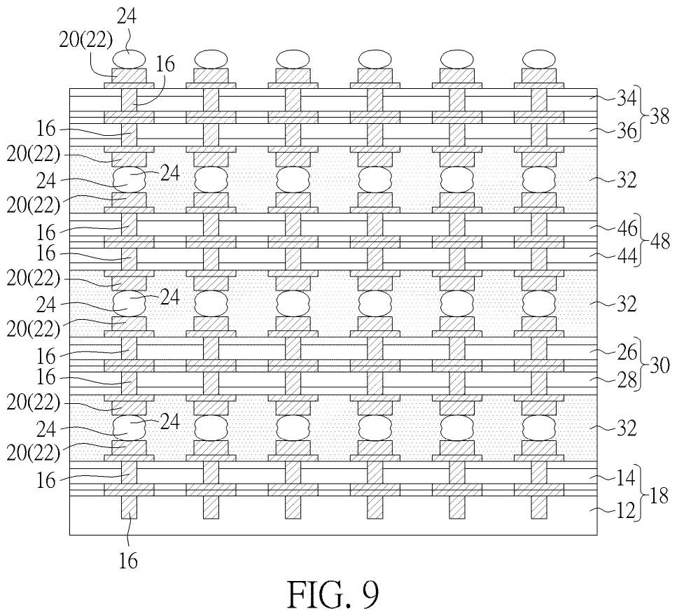

Next, as shown in FIG. 9, a bonding pad formation conducted in FIG. 6 could be carried out by forming a RDL 20, bonding pads 22, and bumps 24 on another side of the third stack structure 38 or on a top surface of the combined structure of the first stack structure 18, the second stack structure 30, the third stack structure 48, and the fourth stack structure 48. This completes the fabrication of a semiconductor device according to an embodiment of the present invention.

Overall, the present invention discloses a wafer to wafer stacking technique applied for high bandwidth memory (HBM) devices, which could be accomplished by first bonding a first wafer to a second wafer to form a first stack structure 18 as shown in FIGS. 1-3, forming a plurality of bumps 24 on one side of the first stack structure, bonding a third wafer to a fourth wafer to form a second stack structure 30 as shown in FIG. 4, forming bumps 24 on one side of the second stack structure, and then bonding the first stack structure 18 to the second stack structure 30 by connecting the bumps on each of the stack structures 18, 30 as shown in FIG. 5. Next, depending on the quantity of stack structures required, the steps of bonding wafers to form stack structure could be repeated to form additional stack structures on previous stack structures.

According to an embodiment of the present invention, means for bonding between wafers and/or stack structures could be accomplished by but not limited to for example hybrid bonding process, micro bump bonding process, or gold bump process. By first stacking wafers to form stack structures and then conducting chip probing (CP) test and repair procedures through the RDL, bonding pads, and bumps on the stack structure, it would be desirable to reduce cycle time and overall cost than conventional approach of first conducting CP test and then stacking wafers afterwards.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
bonding a first wafer to a second wafer to form a first stack structure;
forming first bumps on one side of the first stack structure;
bonding a third wafer to a fourth wafer to form a second stack structure;
forming second bumps on one side of the second stack structure; and
bonding the first stack structure to the second stack structure by bonding the first bumps and the second bumps.

2. The method of claim 1, further comprising:
forming first direct bond interconnects (DBIs) on the first wafer;
forming second DBIs on the second wafer;
bonding the first wafer and the second wafer by connecting the first DBIs and the second DBIs to form the firs stack structure; and
forming the first bumps on the first stack structure.

3. The method of claim 2, further comprising performing a hybrid bonding process to bond the first wafer and the second wafer.

4. The method of claim 3, further comprising:
forming third DBIs on the third wafer;
forming fourth DBIs on the fourth wafer;
bonding the third wafer and the fourth wafer by connecting the third DBIs and the fourth DBIs to form the second stack structure; and
forming the second bumps on the second stack structure.

5. The method of claim 4, further comprising performing a hybrid bonding process to bond the third wafer and the fourth wafer.

6. The method of claim 1, further comprising:
forming a first seal layer between the first stack structure and the second stack structure; and
forming third bumps on another side of the second stack structure.

7. The method of claim 6, further comprising:
bonding a fifth wafer to a sixth wafer to form a third stack structure;
forming fourth bumps on one side of the third stack structure;
bonding a seventh wafer to an eighth wafer to form a fourth stack structure;
forming fifth bumps on one side of the fourth stack structure;
bonding the third stack structure to the fourth stack structure by bonding the fourth bumps and the fifth bumps;
forming a second seal layer between the third stack structure and the fourth stack structure; and
forming sixth bumps on another side of the fourth stack structure.

8. The method of claim 7, further comprising:
bonding the sixth bumps and the third bumps;
forming a third seal layer between the second stack structure and the fourth stack structure; and
forming seventh bumps on another side of the third stack structure.

9. A semiconductor device, comprising:
a first stack structure comprising:
a first wafer bonded to a second wafer;
a second stack structure bonded to the first stack structure, wherein the second stack structure comprises:
a third wafer bonded to a fourth wafer;
first bumps on a top surface of the first stack structure; and
second bumps on a bottom surface of the second stack structure and directly connected to the first bumps.

10. The semiconductor device of claim 9, further comprising:
first direct bond interconnects (DBIs) in the first wafer;
second DBIs in the second wafer;
third DBIs in the third wafer; and
fourth DBIs in the fourth wafer.

11. The semiconductor device of claim 10, wherein the first DBIs are directly connected to the second DBIs.

12. The semiconductor device of claim 10, wherein the third DBIs are directly connected to the fourth DBIs.

13. The semiconductor device of claim 9, further comprising:
a third stack structure bonded to the second stack structure, wherein the third stack structure comprises:
a fifth wafer bonded to a sixth wafer;
third bumps on a top surface of the second stack structure; and
fourth bumps on a bottom surface of the third stack structure and directly connected to the third bumps.

14. The semiconductor device of claim 13, further comprising:
fifth DBIs in the fifth wafer; and
sixth DBIs in the sixth wafer.

15. The semiconductor device of claim 13, further comprising:
a fourth stack structure bonded to the third stack structure, wherein the fourth stack structure comprises:
a seventh wafer bonded to an eighth wafer;
fifth bumps on a top surface of the third stack structure; and
sixth bumps on a bottom surface of the fourth stack structure and directly connected to the fifth bumps.

16. The semiconductor device of claim 15, further comprising:
seventh DBIs in the seventh wafer; and
eighth DBIs in the eighth wafer.
